(19) United States
(12) Patent Application Publication
(10) Pub. No.: US 2016/0351629 A1
(43) Pub. Date: Dec. 1, 2016

(54) Large-Scale Complementary Macroelectronics Using Hybrid Integration of Carbon Nanotubes and Oxide Thin-Film Transistors

(71) Applicant: University of Southern California, Los Angeles, CA (US)

(72) Inventors: Chongwu Zhou, San Marino, CA (US); Haitian Chen, Los Angeles, CA (US); Yu Cao, Los Angeles, CA (US); Jialu Zhang, Hillsboro, OR (US); Pattaramon Vuttipittayamongkol, Lampang (TH); Fanqi Wu, Los Angeles, CA (US); Xuan Cao, Monterey Park, CA (US)

(21) Appl. No.: 15/167,943

(22) Filed: May 27, 2016

Related U.S. Application Data
(60) Provisional application No. 62/167,177, filed on May 27, 2015.

(51) Int. Cl. H01L 27/28; H01L 29/786; H01L 29/24; H01L 51/00; H01L 51/05

(52) U.S. Cl. CPC H01L 27/286; H01L 51/0048; H01L 51/0566; H01L 29/247; H01L 29/78693; H01L 27/283

(57) ABSTRACT

A method of fabricating a logic element, the method includes forming a p-type nanomaterial thin film transistor on a substrate, forming a n-type metal oxide thin film transistor on the substrate, and connecting the p-type nanomaterial thin film transistor to the n-type metal oxide thin film transistor to form the logic element. The logic element is a hybrid complementary logic element.

### CROSS-REFERENCE TO RELATED APPLICATION

This application claims priority to U.S. Application Ser. No. 62/167,177 filed on May 27, 2015, which is incorporated herein by reference.

### FIELD OF INVENTION

This disclosure relates to hybrid integration of carbon nanotubes transistors and oxide thin-film transistors to form large-scale complementary macroelectronics.

### BACKGROUND

During the past few decades, thin film materials have grown in significance in the development of macroelectronics, such as organic semiconductors, oxide semiconductors (e.g., indium gallium zinc oxide (IGZO)), and more recently carbon nanotubes (CNTs). Organic thin film transistors (TFTs) have shown tremendous improvements in terms of their effective device mobility, making them attractive candidates for the implementation of microelectronics. Fabrications of single-walled carbon nanotubes (SWCNTs) thin-film transistors (TFTs) have been extensively made and developed to replace amorphous-silicon TFTs due to their superior electrical performance in terms of field-effect mobility, on/off current ratio and small operation voltage yet high-speed operation. As synthesized carbon nanotubes (CNTs) have capabilities of being either semiconducting or metallic depending on chirality, there have been efforts to selectively eliminate metallic CNTs in order to increase on/off current ratio of CNT thin films transistors.

Oxide semiconductor TFTs such as IGZO-based TFTs have been successfully employed in pixel driver circuitry for commercial display applications. Despite the advancement in oxide semiconductor TFT technology, oxide semiconductor thin films are usually n-type materials, and it still remains a challenge to produce stable p-type oxide TFTs with high effective TFT mobility for macroelectronics.

### SUMMARY

Carbon nanotube network thin films have emerged as potential building blocks for macroelectronics, such as back-panel organic light emitting diode (OLED) pixel driving circuits for active-matrix flat-panel displays (FPDs), digital circuits, radio frequency identification tags, sensors, and memories. CNT network TFTs exhibit high transparency, high flexibility, low process cost, low processing temperature, and high scalability, features that traditional TFT materials such as amorphous silicon and polycrystalline silicon lack.

Semiconducting carbon nanotubes are usually p-type semiconducting material in atmosphere due to adsorption of oxygen, and techniques to convert CNTs to n-type semiconductors to achieve long term stability (e.g., over multiple years) are still to be developed, and such techniques may also have significant device-to-device variation. The methods described herein allow both p-type and n-type thin film transistors to be fabricated with high device yield, producing complementary macroelectronic circuits with minimal steady state power dissipation, low device-to-device variation, that are suitable for large-scale integration of macroelectronics. The methods described herein can produce TFTs that have environmental and operational stability, allowing their usage in practical macroelectronic applications.

Carbon nanotubes and metal oxide semiconductors have emerged as important materials for p-type and n-type thin film transistors, respectively. However, realizing macroelectronics operating in complementary mode has been challenging due to the difficulty in making n-type carbon nanotube transistors and p-type metal oxide transistors. The methods described herein can produce a hybrid integration of p-type carbon nanotube and n-type indium-gallium-zinc-oxide thin film transistors to achieve large scale (>1000 transistors for 501-stage ring oscillators) complementary macroelectronic circuits on both rigid and flexible substrates. This approach of hybrid integration combines the strength of p-type carbon nanotube and n-type indium-gallium-zinc-oxide thin film transistors, thus circumventing the difficulty of producing n-type CNT and p-type metal oxide TFTs. The methods can offer high device yield and low device variation. Based on the methods described herein, various logic gates (inverter, NAND, and NOR gates), ring oscillators (from 51 stages to 501 stages), and dynamic logic circuits (dynamic inverter, NAND, and NOR gates) can be fabricated.

IGZO can be selected as the channel material for the n-type transistors in the integrated macroelectronic circuits because IGZO is one of the most promising members in the category of amorphous oxide semiconductors that have desirable electrical performance.

The systems, techniques and materials described herein can be used in the fabrication of complementary integrated wearable electronics. For instance, complementary processors on cloth or on surface of machines connected to sensors. Some implementations can be manifested in the processing unit for electronic skins. Moreover, some implementations can be employed in the control units for flexible display applications.

Complementary metal oxide semiconductor (CMOS) logic elements or CMOS logic circuits can be constructed by combining a p-type metal oxide semiconductor (PMOS) and a n-type metal oxide semiconductor (NMOS). A CMOS logic circuit can have low power dissipation and full voltage swings which are nearly symmetric, resulting in larger noise margins. It is thus desirable to manufacture both PMOS and NMOS on the same substrate for an integrated CMOS circuit. While PMOS can be demonstrated with single wall carbon nanotubes (SWNTs) as active channel materials, oxide semiconductors are good candidates for NMOS as it has many advantages over traditional silicon and organic semiconductors such as relatively high carrier mobility, high stability in ambient, low manufacturing cost, transparency, high stability in ambient, and the ability for room-temperature fabrication.

Heavy metal oxides such as indium zinc oxide (IZO), zinc oxide, and indium gallium zinc oxide have high mobility and atmospheric stability. Sputtering and spin coating techniques for depositing the heavy metal oxide have greater ease of precursor preparation compared to solution-processed inkjet printing techniques. However, inkjet printing techniques can be more scalable, and cost efficient with high-resolution patterning because they do not involve clean-room processes.

Carbon nanotubes and indium zinc oxide are outstanding materials for fabricating high performance transistors. The methods disclosed herein for producing complementary inverters composed of thin films of carbon nanotube and indium zinc oxide can avoid the costs and complexity usually associated with their manufacturing.

The methods disclosed herein can use a separated semiconducting CNT solution, which is commercially available, and can form transistors by deposition techniques such as printing, spin coating, drop casting, etc. Such a method does not involve removing metallic nanotubes from existing nanotube devices, which may not be easily scaled up and/or can degrade or even severely damage devices. Printing has the advantage of allowing deposition of CNTs at room temperature, which makes fabrication on flexible substrates possible. In addition, there is need be no photolithography process and no masks involved during the printing process, reducing the cost of fabrication and potentially resulting in shorter fabrication time. Thus, inkjet printing allows low-cost and simpler procedures of patterning both types of semiconductors on the same chip. The inkjet printing techniques disclosed herein also allow for a simple fabrication of both types of transistors on the same substrate without deteriorating their electrical properties.

In one aspect, a method of fabricating a logic element, the method includes forming a p-type nanomaterial thin film transistor on a substrate, forming a n-type metal oxide thin film transistor on the substrate, and connecting the p-type nanomaterial thin film transistor to the n-type metal oxide thin film transistor to form the logic element. The logic element can be a hybrid complementary logic element.

Implementations can include one or more of the following features. Forming the p-type nanomaterial thin film transistor can include dispensing a solution of the nanomaterial on a dielectric layer formed on the substrate, and forming a nanomaterial channel that includes the nanomaterial between electrodes formed on the dielectric layer. Forming the n-type metal oxide thin film transistor can include depositing, by sputtering, a metal oxide thin film on a dielectric layer formed on the substrate, patterning electrodes on the metal oxide thin film to form the n-type metal oxide thin film transistor. Forming the n-type metal oxide thin film transistor can include printing a precursor solution between electrodes formed on a dielectric layer that is formed on the substrate, and annealing the deposited precursor solution to form the n-type metal oxide thin film transistor. The substrate can include flexible polyimide. The nanomaterial thin film can be one or more of carbon nanotubes, graphene, MoS₂, WS₂, MoSe₂, NbSe₂, TaSe₂, NiTe₂, MoTe₂, h-BN, Bi₂Te₃, TiS₂, TaS₂, VSe₂ and ZrS₂. The metal-oxide thin film can be one or more of indium gallium zinc oxide (IGZO), zinc tin oxide (ZTO), indium zinc oxide (IZO), indium zinc tin oxide (IZTO), aluminum oxide (AIO), zinc oxide (ZnO) and indium oxide (In₂O₃). The metal-oxide thin film can include IGZO and the nanomaterial thin film can include carbon nanotubes. A method of forming macroelectronics can include electrically connecting a plurality of logic elements. The macroelectronics can include flat-panel displays.

In one aspect, a logic element, the logic element includes a substrate, a p-type nanomaterial thin film transistor on the substrate, a n-type metal oxide thin film transistor in electrical connection with the p-type nanomaterial thin film transistor on the substrate.

Implementations can include one or more of the following features. The nanomaterial can include one or more of carbon nanotube, graphene, MoS₂, WS₂, MoSe₂, NbSe₂, TaSe₂, NiTe₂, MoTe₂, h-BN, Bi₂Te₃, TiS₂, TaS₂, VSe₂ and ZrS₂. The metal-oxide thin film can include one or more of indium gallium zinc oxide (IGZO), zinc tin oxide (ZTO), indium zinc oxide (IZO), indium zinc tin oxide (IZTO), aluminum oxide (AIO), zinc oxide (ZnO) and indium oxide (In₂O₃). The p-type nanomaterial thin film transistor can include a carbon nanotube thin film transistor, and the n-type metal oxide thin film transistor can include an indium gallium zinc oxide (IGZO) thin film transistor. The logic element can include a dynamic inverter and the carbon nanotubes thin film transistor can be configured to be gated by a clock signal. A ring oscillator can include a plurality of the logic elements. The ring oscillator can be configured to rail-to-rail switch between a supplied voltage and ground. The logic element can include a NAND gate. Large-scale macroelectronics can include at least 200 of the logic element. The p-type nanomaterial thin film transistor can include a carbon nanotube thin film transistor, the n-type metal oxide thin film transistor that includes an indium zinc oxide (IZO) thin film transistor, and the logic element can include an inverter having an output swing of more than 98% and a voltage gain of more than 15. An In to Zn ratio in the IZO thin film can be 2:1. The IZO thin film transistor can include Ti/Au electrodes. The substrate can be a flexible substrate.

The details of one or more embodiments of the invention are set forth in the accompanying drawings and the description below. Other features, objects, and advantages of the invention will be apparent from the description and drawings, and from the claims.

### BRIEF DESCRIPTION OF THE DRAWINGS

FIG. 1A shows a schematic diagram of a CNT/IGZO complementary mode inverter on rigid substrate (left) and same circuit on flexible substrate (right).

FIG. 1B shows schematic diagram conceptually showing the interface between the electrode and the CNT network.

FIG. 1C shows an SEM image of CNT network in the channel of a p-type TFT.

FIG. 1D shows an SEM image of IGZO in an n-type TFT.

FIG. 1E is an optical micrograph of the hybrid CNT/IGZO ring oscillators, inverters, individual p-type, and n-type transistors fabricated on a rigid Si/SiO₂ substrate.

FIG. 1F is an image of the hybrid CNT/IGZO ring oscillators, inverters, and individual transistors on a flexible polyimide substrate laminated on a polydimethylsiloxane (PDMS) film.

FIG. 1G shows transfer characteristic in linear and log scale, and transconductance of a CNT TFT.

FIG. 1H shows output characteristics of the CNT TFT over a range of V_{DS}.

FIG. 1I shows transfer characteristics in linear and log scale, and transconductance of a IGZO TFT.

FIG. 1J shows output characteristics of an IGZO TFT.

FIG. 2A shows individual bottom-gate electrodes.

FIG. 2B shows the deposition of a layer of Al₂O₃ and a layer of SiOₓ on the electrodes.

FIG. 2C shows incubation of 98% semiconducting enriched CNT solution on the surface of the sample.

FIG. 2D shows CNT channels being defined.

FIG. 2E shows vias or interconnects between devices and probing window on testing pads for gate electrodes.

FIG. 2F shows electrodes for the p-type CNT TFTs.

FIG. 2G shows a layer of 50 nm of IGZO thin film deposited by DC magnetron sputtering.

FIG. 2H shows patterning and metallization of electrodes for the n-type IGZO TFTs.

FIG. 3A shows a histogram of the mobility of 20 CNT devices.

FIG. 3B shows a histogram of the current on/off ratio (log₁₀(Iₒₙ/I_{off})) measured from the same 20 devices.

FIG. 3C shows a histogram of the threshold voltage (Vₜₕ) measured from the 20 CNT TFTs.

FIG. 3D shows a histogram of the mobility exhibited by 20 IGZO devices fabricated on a rigid substrate.

FIG. 3E shows a histogram of log₁₀(Iₒₙ/I_{off}) measured from the same 20 devices as in FIG. 3D.

FIG. 3F shows a histogram of Vₜₕ measured from the 20 IGZO TFTs.

FIG. 4A shows a schematic diagram and an optical micrograph of a hybrid CNT/IGZO inverter.

FIG. 4B shows output voltage and current characteristics of the hybrid inverter fabricated on a rigid substrate.

FIG. 4C shows the voltage gain of the inverter.

FIG. 4D shows output characteristics of 20 hybrid CNT/IGZO inverters fabricated on a polyimide flexible substrate.

FIG. 4E shows the voltage gain of the 20 inverters.

FIG. 4F shows the threshold voltage (at Vₒᵤₜ=Vᵢₙ) of the 20 inverters.

FIG. 5A shows a schematic diagram and an optical micrograph of a hybrid CNT/IGZO NAND gate on a rigid substrate.

FIG. 5B shows output characteristics of the hybrid CNT/IGZO NAND gate.

FIG. 5C shows a schematic diagram and an optical micrograph of a hybrid CNT/IGZO NOR gate on a rigid substrate.

FIG. 5D shows output characteristics of the hybrid CNT/IGZO NOR gate.

FIG. 5E shows a schematic diagram and an optical micrograph of a hybrid NAND gate fabricated on a polyimide substrate.

FIG. 5F shows output characteristics of the hybrid NAND gate.

FIG. 5G shows a schematic diagram and an optical micrograph of a hybrid NOR gate fabricated on a polyimide substrate.

FIG. 5H shows output characteristics of the hybrid NOR gate.

FIG. 6A shows an optical micrograph and a schematic diagram of a 51-stage ring oscillator.

FIG. 6B shows output characteristics of a 51-stage ring oscillator.

FIG. 6C shows an optical micrograph of a 101-stage ring oscillator.

FIG. 6D shows the output characteristics of the 101-stage ring oscillator shown in FIG. 6C.

FIG. 6E shows an optical micrograph of a 251-stage ring oscillator.

FIG. 6F shows output characteristics of the 251-stage ring oscillator shown in FIG. 6E.

FIG. 6G shows an optical micrograph of a 501-stage ring oscillator.

FIG. 6H shows output characteristics of the 501-stage ring oscillator shown in FIG. 6G.

FIG. 61 shows the frequency of the output signals of the 51-stage, 101-stage, 251-stage, and 501-stage ring oscillators.

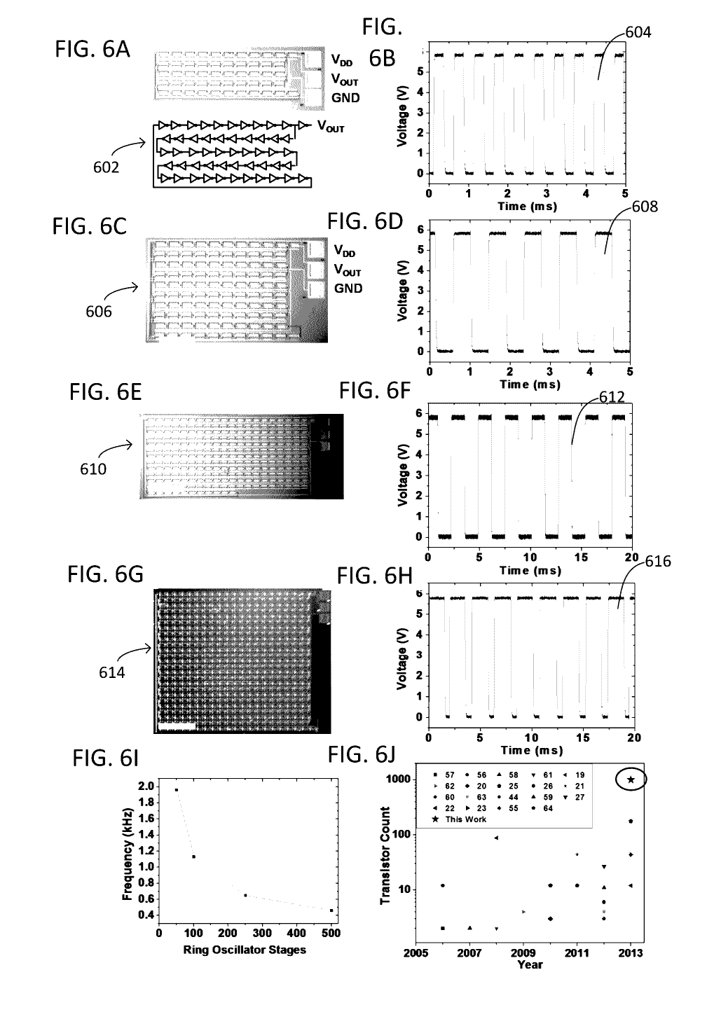

FIG. 6J shows a comparison of the level of integration of CNT-based integrated circuits.

FIG. 7A shows an optical micrograph and output characteristics of a 251-stage hybrid complementary ring oscillator fabricated on a flexible polyimide substrate.

FIG. 7B shows an optical micrograph and output characteristics of a 501-stage hybrid complementary ring oscillator fabricated on a flexible polyimide substrate.

FIG. 8A shows a schematic diagram of a dynamic inverter based on the hybrid CNT/IGZO complementary scheme.

FIG. 8B shows an optical micrograph of the dynamic inverter shown in FIG. 8A.

FIG. 8C shows output characteristics of the dynamic inverter.

FIG. 8D shows a schematic diagram of a dynamic NAND gate.

FIG. 8E shows an optical micrograph of the dynamic NAND gate shown in FIG. 8D.

FIG. 8F shows output characteristics of the dynamic NAND gate.

FIG. 8G shows a schematic diagram of a dynamic NOR gate.

FIG. 8H shows an optical micrograph of the dynamic NOR gate shown in FIG. 8G.

FIG. 81 shows output characteristics of the dynamic NOR gate.

FIG. 9A shows a schematic diagram of the printed complementary inverter fabrication process.

FIG. 9B shows a schematic diagram of the printed complementary inverter fabrication process.

FIG. 9C shows an optical image of printed CNT TFT (before annealing).

FIG. 9D shows a SEM image of the carbon nanotube network in the channel region.

FIG. 9E shows an optical image of a printed IZO TFT (after annealing).

FIG. 9F shows a SEM image of a printed back-gated IZO TFT.

FIG. 10A shows output (I_{D}-V_{D}) characteristics of a representative CNT TFT in saturation regime.

FIG. 10B shows transfer (I_{D}-V_{G}) characteristics and gₘ-V_{G} characteristics of the same CNT TFT.

FIG. 10C shows statistical analysis of the threshold voltage distribution among 20 CNT TFTs.

FIG. 10D shows output (I_{D}-V_{D}) characteristics of a representative IZO in saturation regime.

FIG. 10E shows transfer (I_{D}-V_{G}) characteristics and gₘ-V_{G} characteristics of the same IZO TFT.

FIG. 10F shows a statistical analysis of threshold voltage distribution among 20 IZO TFTs.

FIG. 11A shows output (I_{D}-V_{D}) characteristics of a representative CNT TFT in saturation regime.

FIG. 11B shows transfer (I_{D}-V_{G}) characteristics of the same CNT device.

FIG. 11C shows a statistical analysis of threshold voltage distribution among 20 printed CNT TFTs.

FIG. 12A shows transfer (I_{D}-V_{G}) characteristics of IZO TFTs with different In-to-Zn ratios.

FIG. 12B shows output (I_{D}-V_{D}) characteristics of a representative IZO TFT with In:Zn=1:1 in saturation regime.

FIG. 12C shows transfer (I_{D}-V_{G}) characteristics of the same IZO TFT with In:Zn=1:1.

FIG. 12D shows output (I_{D}-V_{D}) characteristics of a representative IZO TFT with In:Zn=3:1 in saturation regime.

FIG. 12E shows transfer (I_{D}-V_{G}) characteristics of the same IZO TFT with In:Zn=3:1.

FIG. 13A shows voltage transfer (V_{OUT}-V_{IN}) characteristics of one representative printed complementary inverter.

FIG. 13B shows a switching current (I_{D}-V_{IN}) curve of the same complementary inverter.

FIG. 13C shows the gain of the same complementary inverter.

Like reference symbols in the various drawings indicate like elements.

### DETAILED DESCRIPTION

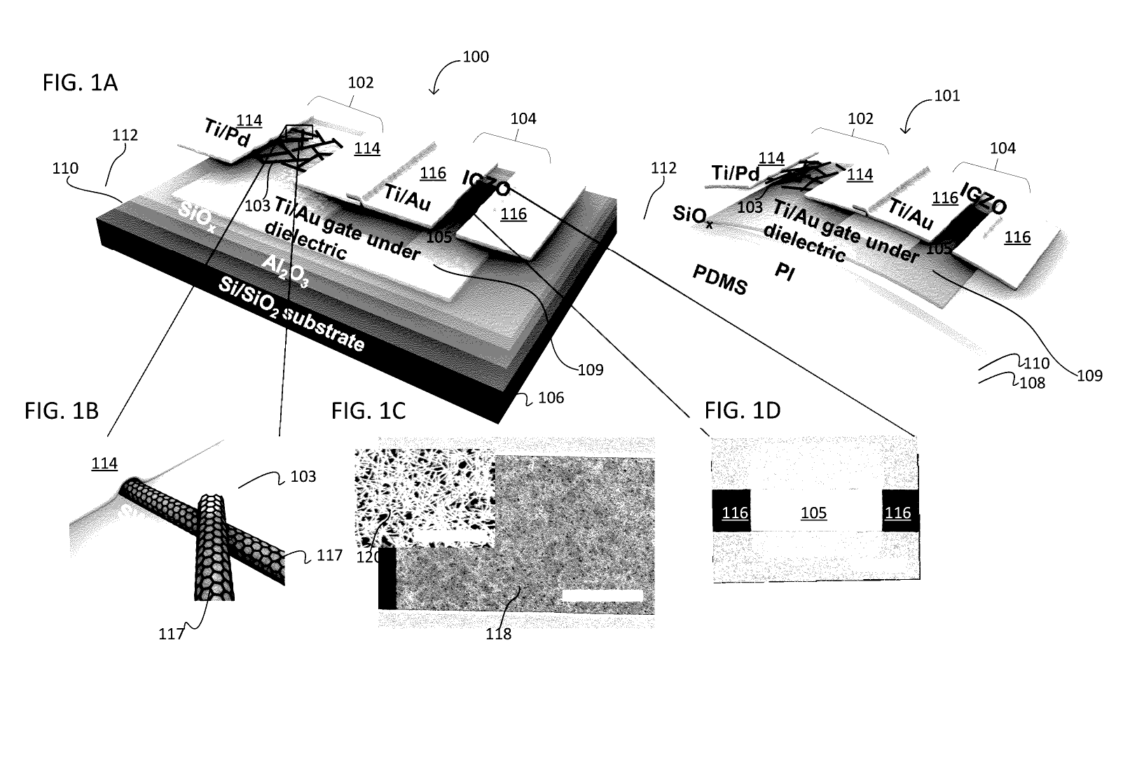

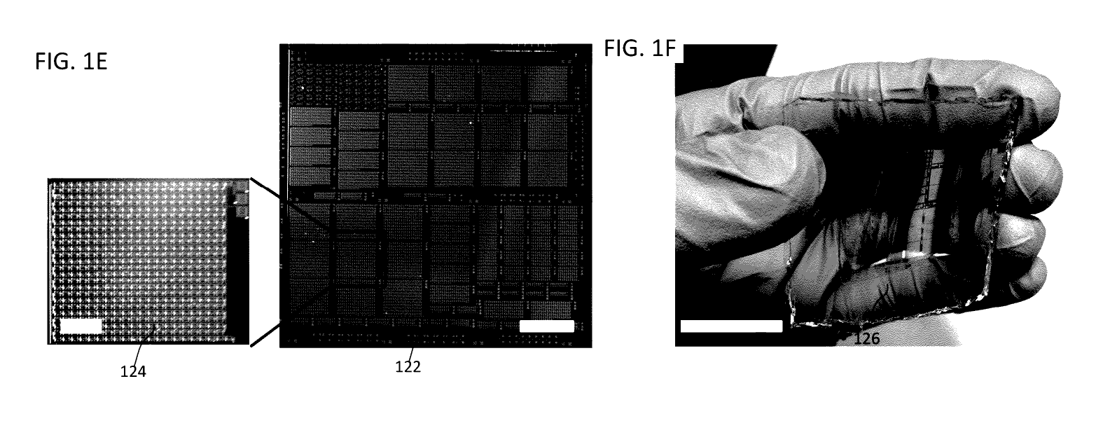

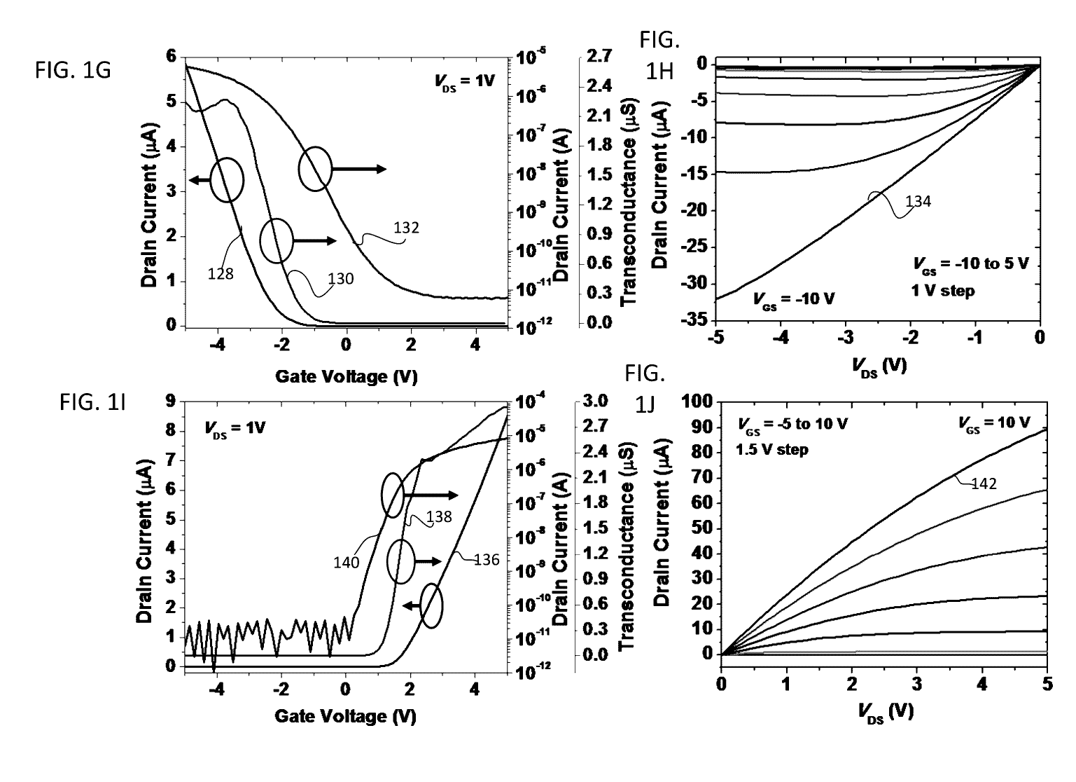

FIG. 1A show an inverter 100, which includes an example of hybrid integration of a CNT network transistor 102 and an IGZO thin film transistor 104. The inverter 100 can be fabricated on both a rigid substrate 106, such as a Si/SiO₂ substrate, and a flexible substrate 108, such as an inverter 101 on a polyimide substrate.

The inverter 100 has an individual back-gate design. Briefly, individual back-gate electrodes 109 were patterned and deposited on the substrate 106. The back-gate electrodes 109 can be formed of Ti/Au. After patterning and depositing the back-gate electrodes 109, dielectric materials such as, for example, Al₂O₃ and SiOₓ are sequentially deposited. Alternatively, HfO₂ and SiOₓ can be used. In the embodiment shown in FIG. 1A, a layer 110 of Al₂O₃ is first deposited, followed by a layer 112 of SiOₓ. The layer 110 can be, for example, 10 nm or more, 20 nm or more, 30 nm or more, 40 nm or more, 50 nm or more, 100 nm or more. The layer 112 can be, for example 1 nm or more, 2 nm or more, 5 nm or more, 10 nm or more. The substrate 106 bearing the deposited electrodes 109 and the layers 110 and 112 can be incubated in a poly-L-lysine solution, for example, for less than 10 minutes (e.g., for 6 minutes). A thin layer of poly-L-lysine remains on the layer 112 after the bulk of the poly-L-lysine solution is washed away with deionized (DI) water and dried with N₂ air gun. The thin layer of poly-L-lysine can serve as an adhesive layer for the CNTs.

A CNT network 103 is deposited by incubating the substrate containing the layer of poly-L-lysine in a semiconducting nanotubes solution. The semiconducting nanotubes solution can contain more than 95% of semiconducting nanotubes, for example, 98% or 99% of semiconducting nanotubes. The substrate is then rinsed with DI water and dried with N₂ air gun so that a uniform carbon network 103 is left on the substrate 106.

The 98% semiconducting CNT network solution was used as purchased from Nanolntegris Inc., of Menlo Park, Calif. The 98% semiconducting CNT network solution can be formed by a density gradient ultracentrifugation (DGU) approach that is used to separate semiconducting and metallic nanotubes.

The CNT thin film is patterned to provide a specific channel geometry for the p-type CNT TFT 102. Thereafter, electrodes 114 are formed by metallization. Electrodes 114 can be formed of Ti/Pd. A layer 105 of IGZO thin film is then deposited as the channel material for the n-type IGZO device 104. The IGZO thin film 105 can be deposited using RF magnetron sputtering. Standard photolithography and metallization are used to form electrodes 116 of the n-type TFTs. Electrode 116 can be formed of Ti/Au.

FIG. 1B conceptually illustrates the interface between the CNT random network 103 and the electrode 114. Two randomly oriented single wall carbon nanotubes (SWNT) 117 of the random network 103 cross each other.

FIG. 1C shows scanning electron microscopic (SEM) images of the CNT network 103 in the device channel of a p-type transistor. Image 118 shows a lower-magnification SEM image of the random network 103, and image 120 shows a higher-magnification image of the CNT network in which individual strands of the CNTs can be seen. The scale bar in the low magnification SEM image is 10 μm and the scale bar in the high magnification SEM image is 2 The SEM images 118 and 120 in FIG. 1C show the uniform network of CNTs in the device channel. By modifying the CNT incubation time, the density of the CNTs in the channel can also be modified to control the metrics of performance of the p-type devices.

FIG. 1D shows an SEM image of the IGZO thin film 105 in the channel of n-type transistors 104. The SEM image shows Ti/Au electrodes 116. The scale bar is 5 μm.

FIG. 1E shows optical images of hybrid integrated CNT/IGZO complementary circuits such as ring oscillators, inverters, individual p-type, and n-type transistors, on a rigid substrate. The ring oscillators include 501-stage ring oscillators, 251-stage ring oscillators, 101-stage ring oscillators, and 51-stage ring oscillators. Image 122 is a lower magnification inset and image 124 shows a magnified image of a portion of the circuits that contains a 501-stage ring oscillator on the rigid substrate. The scale bar in the rigid circuit chip is 500 The scale bar in the 501-stage ring oscillator image is 600 μm.

FIG. 1F shows an optical image of hybrid integrated CNT/IGZO complementary circuits on a flexible substrate 126 that is being flexed. The flexible substrate 126 can be a flexible polyimide membrane. A suitable susbtrate is for example, flexible polyimide membrane PI-2525, obtained from HD MicroSystems Inc., of Parlin, N.J. The methods and devices described herein are suitable for large scale integration of flexible electronics using CNT TFTs. The electrical performances of the hybrid CNT/IGZO integrated circuits shown in FIGS. 1A-1F are characterized as described below.

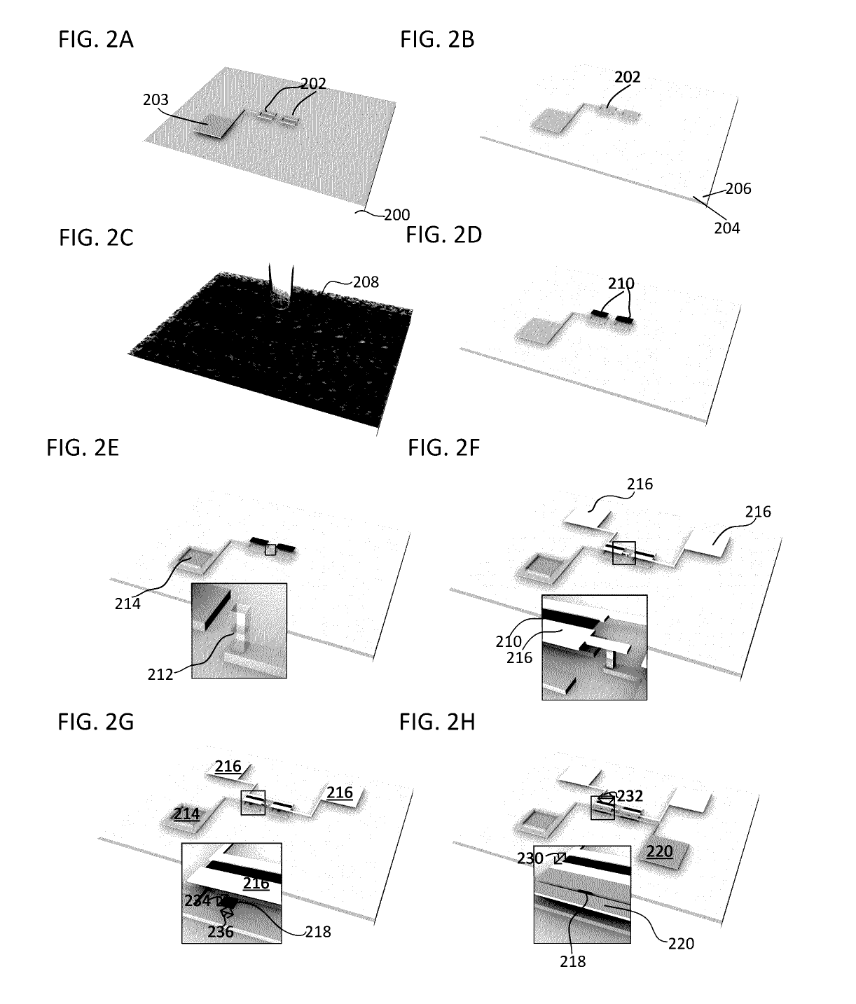

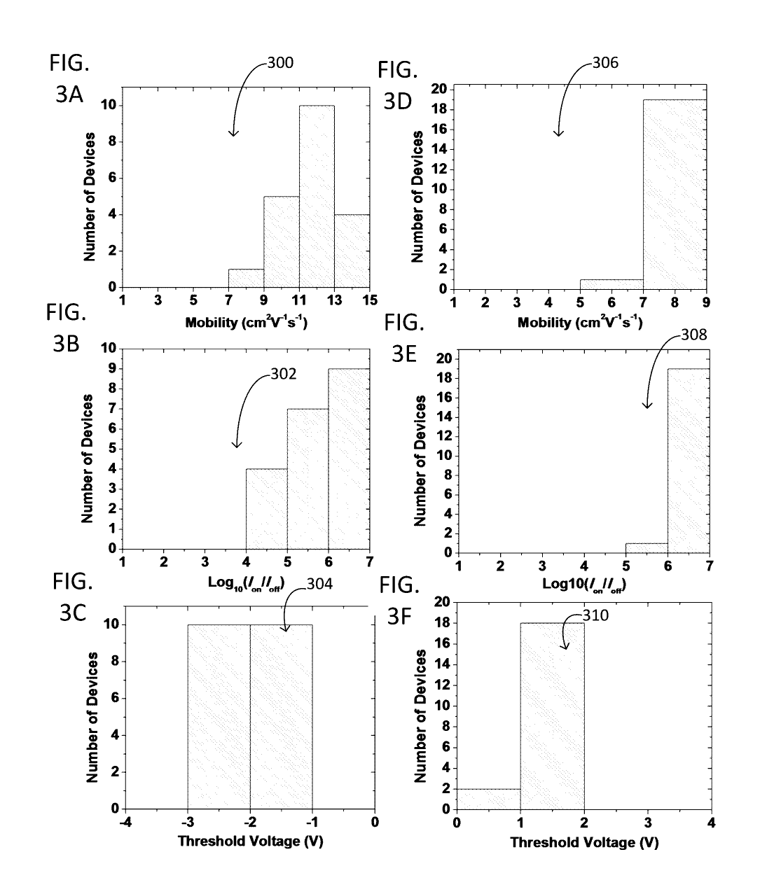

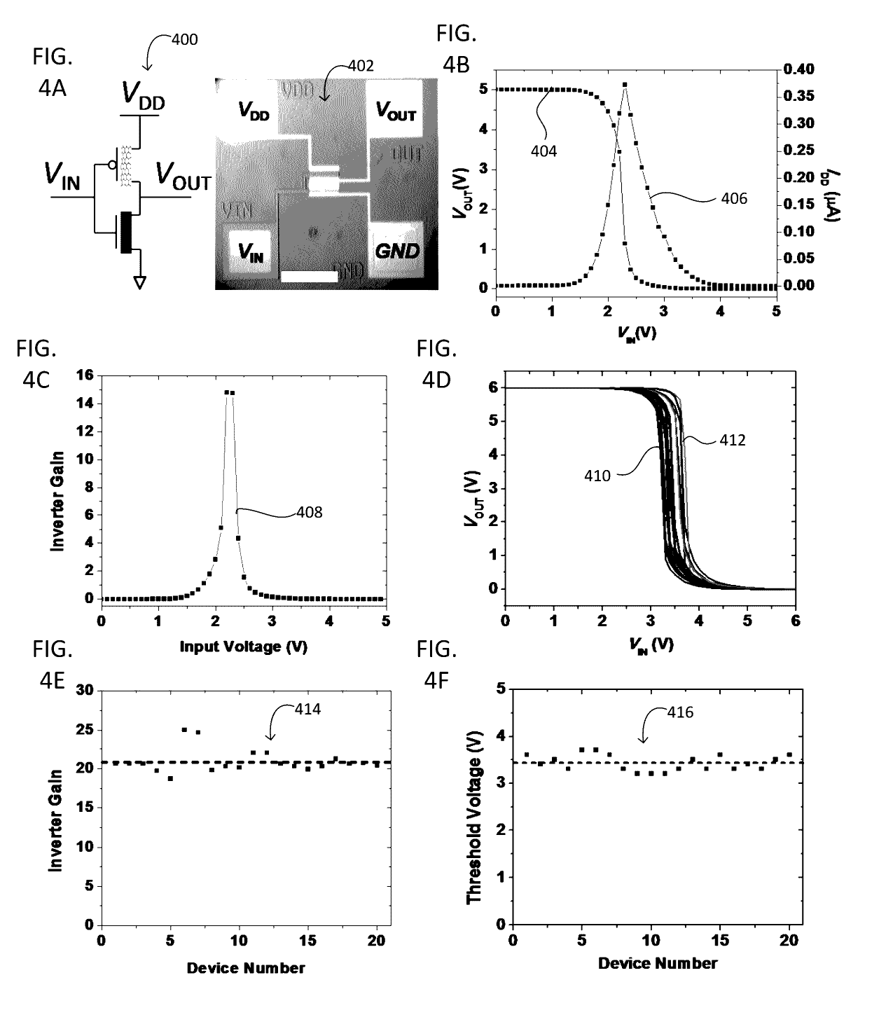

FIGS. 1G and 1H show the electrical performance of an individual p-type CNT TFT. A transfer characteristic curve 128 of drain current as a function of gate voltage in FIG. 1G shows that the CNT TFT exhibits a p-type transistor behavior. A curve 132 shows the characteristic curve in logarithmic scale. A curve 130 shows the transconductance of a CNT TFT as a function of gate bias from −5V to 5V. The drain-to-source voltage V_{DS} is kept constant at 1V. The typical device current on/off ratio (Iₒₙ/I_{off}) and mobility are ˜10⁵-10⁶ and 8-15 cm²V⁻¹s⁻¹, respectively. Based on the curve, the p-type CNT device turn on at −2V. In the examples of devices described herein, a channel length, L_{ch}, 230 (shown in FIG. 2H) and a width, W_{ch}, 232 of the p-type transistors are 20 μm and 100 μm respectively. The mobility was calculated based on the formula, μ=(L_{ch}/W_{ch})[1/(C·V_{DS})](dl_{DS}/dV_{GS}), where C is the gate capacitance estimated with the network model. FIG. 1H shows a plot 134 of drain current as a function of drain-to-source voltage. The transistor can be fully saturated as depicted in FIG. 1H.

FIG. 1I illustrates the transfer and output characteristics curve 136 of an individual n-type IGZO TFT having a channel length 234 (shown in FIG. 2G) of 4 μm and a channel width 236 (shown in FIG. 2G) of 12 μm. The typical Iₒₙ/I_{off} and mobility of an n-type device are ˜10⁶ and ˜7-8 cm²V⁻¹s⁻¹, respectively. The n-type device turns on approximately at 1.8V. Curve 138 shows the transconductance of a IGZO TFT as gate bias is varied from −5 to 5V. And curve 140 shows the drain current as a function of gate voltage in logarithmic scale. FIG. 1J shows an output characteristics curve 142 of the IGZO TFT.

FIGS. 2A-2H illustrate an example of a fabrication procedure of hybrid CNT/IGZO complementary integrated circuits. Individual bottom-gate electrodes 202 shown in FIG. 2A are patterned by photolithography on a substrate 200. FIG. 2A also shows a test pad 203 for the gate electrodes 202. The substrate 200 can be a highly doped p-Si substrate having a layer of thermally grown oxide thereon. For example, the thermally grown oxide can have a thickness of about 300 nm. E-beam evaporation can then be used to deposit the metal that forms the electrodes 202. For example, Ti/Au can be used. In the embodiment shown in FIG. 2A, 5 nm of Ti is first deposited before 50 nm of Au is deposited. The Ti can serve as an adhesion layer.

FIG. 2B shows a first layer 204 of dielectric material deposited on the substrate 200 and covering the electrodes 202. The first layer 204 of dielectric material can be made of Al₂O₃. Other materials such as HfO₂ can also be used. The Al₂O₃ can have a thickness of, for example, less than 100 nm, less than 90 nm, less than 80 nm, less than 70 nm, less than 60 nm, less than 50 nm, less than 40 nm, less than 30 nm, less than 20 nm. The Al₂O₃ layer can be deposited using atomic layer deposition (ALD) at, for example, 250° C. In the embodiment shown in FIG. 2B, 40 nm of Al₂ O₃ is deposited on the electrodes 202. A second layer 206 of dielectric material is then deposited on top of the layer 204. The second layer 206 of dielectric material can be SiOₓ. Alternatively, HfO₂ and SiOₓ can be used. For example, the second layer 206 can be a 5 nm thick layer of SiOₓ deposited using e-beam evaporation. The layers 204 and 206 jointly form the dielectric layer for circuits fabricated using the procedure illustrated in FIGS. 2A-2H. Prior to depositing carbon nanotubes onto the second layer 206 of dielectric material, the surface of the second layer 206 can be functionalized by poly-L-lysine. For example, 0.1% wt poly-L-lysine in water from Ted Pella Inc., of Redding, Calif. can be used to form an amine terminated surface. Drop casting the poly-L-lysine solution can cover the surface of the second layer 206 of dielectric material with poly-L-lysine. The surface can then be incubated in the solution for less than 10 minutes (e.g., less than 8 minutes, about 6 minutes). After the incubation, deionized (DI) water can be used to remove excess poly-L-lysine solution.

FIG. 2C shows a solution 208 in contact with the second layer 206 of dielectric material having a functionalized surface. The solution can be a semiconducting enriched CNT solution, for example, an 98% semiconducting enriched CNT solution. In some embodiments, the solution 208 is a 0.01 mg/mL 98% semiconducting CNT obtained from Nanolntegris Inc., of Menlo Park, Calif. The solution 208 can be dispensed from a micropipette by dropping to fully cover the surface of the functionalized sample. The sample bearing the dropped solution can be left in air for about 10 minutes, and then rinsed with deionized water before being dried with N₂ gas. This process produces a surface that is covered with CNT.

FIG. 2D shows CNT channels 210 that are defined by photolithography followed by O₂ plasma etching to remove the CNT materials from regions outside of the desired channels 210. For example, plasma etching can be conducted at 100 W/150 mTorr for less than 2 minutes, for example, 1 minute and 15 seconds.

FIG. 2E shows a via 212 (or interconnect) between devices, and a probing window 214 on the testing pad 203 for the gate electrodes 202. The via 212 and the probing window 214 are patterned by photolithography and the dielectric material at the via 212 and on the testing pad 203 can be etched by a buffered oxide etchant. For example, a buffered HF 7:1 solution can be used to etch the structures for, for example, 1 minute and 20 seconds.

FIG. 2F shows electrodes 216 for p-type CNT TFTs that are first defined by photolithography and then formed by e-beam evaporation. For example, electrode 216 can be formed by Ti/Pd. In some embodiments, 1 nm of Ti is deposited followed by 50 nm of Pd.

FIG. 2G shows a layer 218 of IGZO thin film. The layer 218 of IGZO can be less than 100 nm, less than 80 nm, less than 60 nm, or about 50 nm, and the thin film layer 218 can be deposited by DC magnetron sputtering, for example, at 180 W after photolithography is used to defined the channels into which IGZO is deposited to form the IGZO channels.

FIG. 2H shows electrodes 220 patterned and metallized using, for example, Ti/Au to form a n-type IGZO thin-film transistor. In some embodiments, 1 nm of Ti is deposited followed by 50 nm of Au using an e-beam evaporator. The fabrication process detailed in FIGS. 2A-2H to form devices based on CNT and IGZO can be conducted at room temperature, which is compatible with current flat-panel display manufacturing processes. The ability for fabrication to be conducted at room temperature is also desirable for flexible electronics.

The fabrication of the CNT/IGZO hybrid complementary circuits can be conducted on a flexible substrate (e.g., polyimide) using a similar procedure as that outlined above. For flexible substrates, such as polyimide, an initial layer of polyimide (for example, obtained as PI-2525 from HD MicroSystems, Inc., of Parlin, N.J.) can be spun on a rigid substrate, such as a silicon supporting wafer at a speed of, for example, 2000 rpm for 30 seconds. The material can be baked at 120° C. for 30 seconds, and then baked at 150° C. for 30 seconds. A second layer of polyimide (PI) can be spun onto the sample and baked under the same conditions. Then the sample can be cured in argon gas at a temperature of 200° C. for 30 minutes with a ramping rate of 4° C./min. After the temperature is raised to 300° C. at a ramping rate of 2.5° C./min., the temperature can be sustained at the same level for 60 minutes. The thickness of the final PI film can be approximately 24 μm. The circuits can then be fabricated onto the polyimide substrate based on the procedure described above. The fully fabricated circuits along with the polyimide film can be delaminated from the Si/SiO₂ substrate, and then laminated onto a polydimethylsiloxane (PDMS) substrate as a support to form a flexible IC chip.

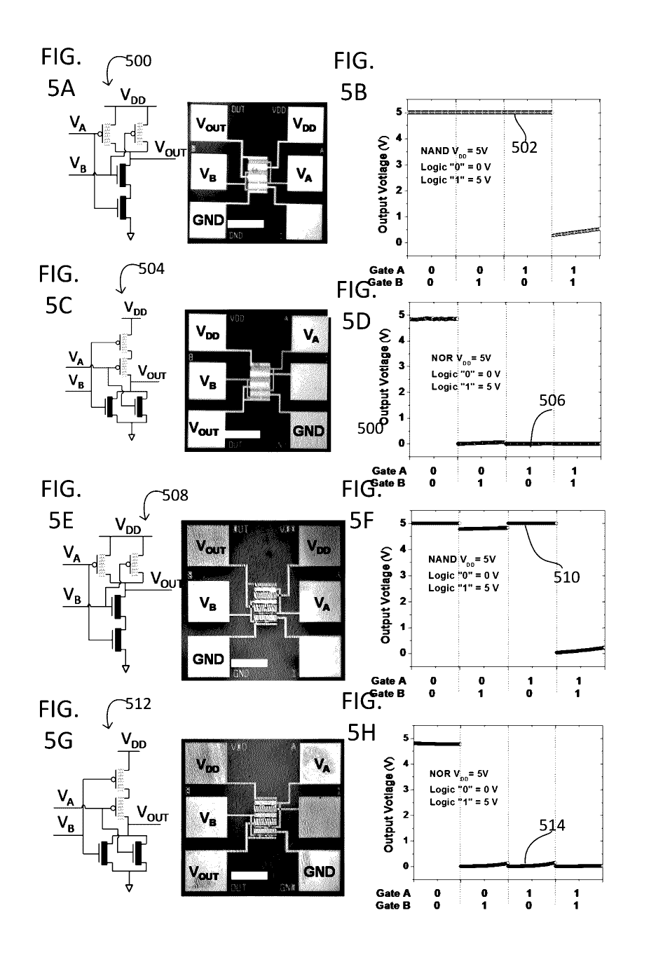

The performance of 20 individual p-type CNT and n-type IGZO TFTs was measured, and they exhibited relatively uniform results as shown in FIGS. 3A-F. FIG. 3A shows a histogram 300 of the mobility of 20 CNT devices fabricated on a rigid substrate. The 20 CNT devices have an average mobility of 11.8 cm²V⁻¹s⁻¹ with 10 of the devices showing mobility between 11 and 13 cm²V⁻¹s⁻¹. FIG. 3B shows a histogram 302 of the log of the current on/off ratio from the same 20 devices with 16 devices showing Iₒₙ/I_{off} between 1×10⁵ and 1×10⁷. FIG. 3C shows a histogram 304 of the threshold voltage (Vₜₕ) measured from the 20 CNT TFTs. The mean Vₜₕ is −2.2V, and all of the devices showing Vₜₕ between −3 and −1V.

FIG. 3D shows a histogram 306 of the mobility of 20 IGZO devices fabricated on a rigid substrate. 18 of the devices show mobility between 7-9 cm²V⁻¹s⁻¹. FIG. 3E shows a histogram 308 of the log of the current on/off ratio from the same 20 devices. 19 devices show Iₒₙ/I_{off} between 1×10⁶ and 1×10⁷. FIG. 3F shows a histogram 310 of the threshold voltage (Vₜₕ) measured from the 20 IGZO TFTs. The 20 IGZO TFTs have a mean Vₜₕ of 1.2V and 18 of the devices show Vₜₕ between 1V and 2V.

The results shown in FIGS. 3A-3F indicate that circuits operating in complementary mode (i.e., coupling the p-type TFTs with the n-type TFTs) can be actualized based on the desirable p-type and n-type behavior of these TFTs. CNT TFTs and IGZO TFTs can serve as an ideal pair of materials for complementary integrated circuits.

FIGS. 4A-4C relate to a hybrid CNT/IGZO inverter 400 formed on a rigid substrate and FIGS. 4D-4F relate to a hybrid CNT/IGZO inverter 400 formed on a flexible substrate. FIG. 4A shows a schematic diagram and an optical micrograph of the hybrid CNT/IGZO inverter 402 fabricated on a rigid Si/SiO₂ substrate. The scale bar is 200 μm. V_{DD} is the voltage supplied to the circuits (i.e., the CNT and the IGZO TFTs). V_{OUT} corresponds to the output signal of the circuits. V_{IN} corresponds to the input signal of the inverter and GND is designated as the ground of the circuits. In the embodiment shown in FIG. 4A, the supply voltage (V_{DD}) and the ground (GND) of the inverter were connected to 5V and 0V, respectively, during the characterization.

FIG. 4B shows a voltage plot 404 of the rail-to-rail output of the inverter 402. The measured inverter threshold voltage is ˜2.4V, which is nearly half of the V_{DD}. FIG. 4B also shows a current plot 406. For an input signal V_{IN} below 1V or above 4V, the inverter current is around 190 pA, demonstrating the low steady-state power dissipation advantage of the hybrid complementary TFT structure of inverter 400. FIG. 4C shows an inverter gain curve 408, having a maximum gain of ˜15.

FIG. 4D illustrates the uniformity of the performance of 20 hybrid CNT/IGZO inverters fabricated on a flexible polyimide substrate. FIG. 4D shows plots, such as curves 410 and 412, of the output signal as a function of the input signal for all 20 inverters. The 20 inverters were measured in the same region of the chip, and the yield of the circuits is 100%. This demonstrates the high-yield and practicality of implementing this hybrid circuit scheme for both rigid and flexible circuit applications. The uniformity of the performance of the 20 inverters in terms of their voltage gain and threshold voltage is shown in FIGS. 4E and 4F. FIG. 4E shows a plot 414 of the inverter voltage gain of the 20 inverters. The mean value of the voltage gain is 20.9 and has a standard deviation of 1.5. FIG. 4F shows a plot 416 of the threshold voltage (at Vₒᵤₜ=Vᵢₙ) of the 20 inverters. The mean value of the threshold voltage is 3.4V and has a standard deviation of 0.17V.

FIG. 5A shows a schematic diagram and an optical micrograph of two-input NAND gate 500 fabricated based on the CNT/IGZO hybrid design on a rigid substrate. The scale bar in FIG. 5A is 200 μm. VA and VB are used to designate the two input signals of circuits. V_{DD}, V_{OUT} and GND correspond to the supplied voltage, the output signal and the ground of the NAND gate. FIG. 5B shows an output voltage 502 as a function of different inputs at the two inputs (i.e., gate A and gate B). A supplied voltage of 5V was supplied to the circuit during measurement. Input signals of “00”, “01”, “10” and “11” were supplied to the logic gate. The output voltage 502 of the NAND gate correctly returns a signal ‘0’ only when both of the inputs at gate A and gate B are ‘1’. In that logic configuration, both of the p-type CNT transistors are turned off.

FIG. 5C shows a two-input NOR gate 504 fabricated based on the CNT/IGZO hybrid design on a rigid substrate. FIG. 5D shows an output voltage 506 as a function of different inputs at the two inputs (i.e., gate A and gate B). V_{A} and V_{B} are used to designate the two input signals of circuits. V_{DD}, V_{OUT} and GND correspond to the supplied voltage, the output signal and the ground of the NAND gate. Both of the NAND gate and NOR gate demonstrate a rail-to-rail voltage swing from 0V to 5V at a supply voltage of 5V, showing the robust complementary mode of operation of the CNT/IGZO hybrid design. The voltage output 506 of the NOR gate correctly returns an output of “1” only when both of the inputs at gate A and gate B are set to “0”. The logic configuration corresponds to both of the n-type IGZO transistors being turned off. FIGS. 5B and 5D show that the circuits return correct output signals based on the corresponding input logics. As NAND and NOR gates are some of the basic building blocks in modern digital integrated circuits, the embodiments shown in FIGS. 5A and 5C suggest that more complex digital circuits with the hybrid circuit design can be fabricated.

FIG. 5E and FIG. 5G show a schematic diagram and an optical micrograph of a CNT/IGZO hybrid integrated two input NAND gate 508 and a two input NOR gate 512, respectively, both fabricated on a flexible polyimide thin film. The supply voltage of the two logic circuits is also 5V. FIG. 5F shows output voltage 510 as a function of various inputs to the NAND gate. FIG. 5H shows an output voltage 514 as a function of various inputs to the NOR gate. The output signal of the two logic gates demonstrate that the CNT/IGZO hybrid integrated circuits returned correct logic output signals based on the corresponding input logics while operating on flexible substrates. The hybrid CNT/IGZO circuit configuration for circuits built on both rigid and flexible substrates can thus be implemented.

FIG. 6A show a schematic diagram and an optical micrograph of a 51-stage ring oscillator 602 on a rigid substrate. The scale bar is 400 μm. The labels V_{DD}, V_{OUT} and GND correspond to the supplied voltage, the output voltage and the ground for the ring oscillators. In the oscillator, 51 hybrid CNT/IGZO complementary inverters are connected in series with an additional inverter connected at the output of the oscillator functioning as a buffer stage.

FIG. 6B shows output characteristics 604 of the oscillator 602. FIG. 6C shows a 101-stage ring oscillator 606 and FIG. 6D shows output characteristics 608 of the oscillator 606. FIG. 6E shows a 251-stage ring oscillator 610 and FIG. 6F shows output characteristics 612 of the oscillator 610. FIG. 6G shows a 501-stage ring oscillator 614 and FIG. 6F shows output characteristics 616 of the oscillator 614.

With the ideal inverter behavior manifested by the hybrid CNT/IGZO integrated circuit, the hybrid design enables implementation of 51-stage, 101-stage, 251-stage and 501-stage ring oscillators, and they all generated output signals with rail-to-rail output voltage swing from 0 to 6V. The 501-stage hybrid CNT/IGZO integrated ring oscillator has 1004 transistors.

All of the results shown in FIGS. 6A-6I were obtained from the circuits fabricated on one single chip, underscoring the robustness of hybrid CNT/IGZO design.

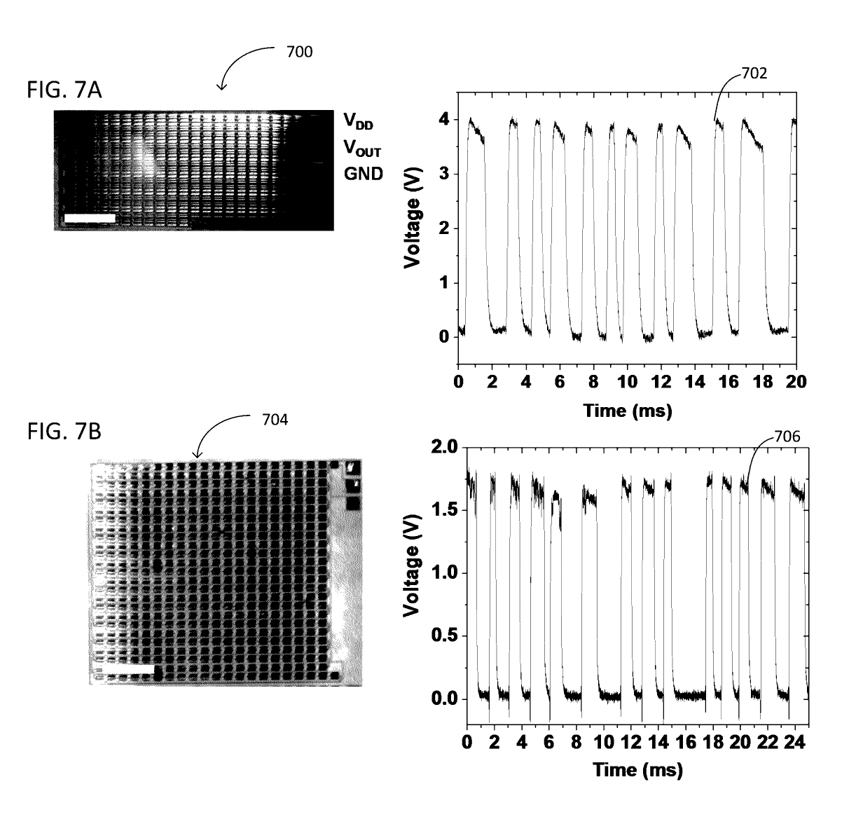

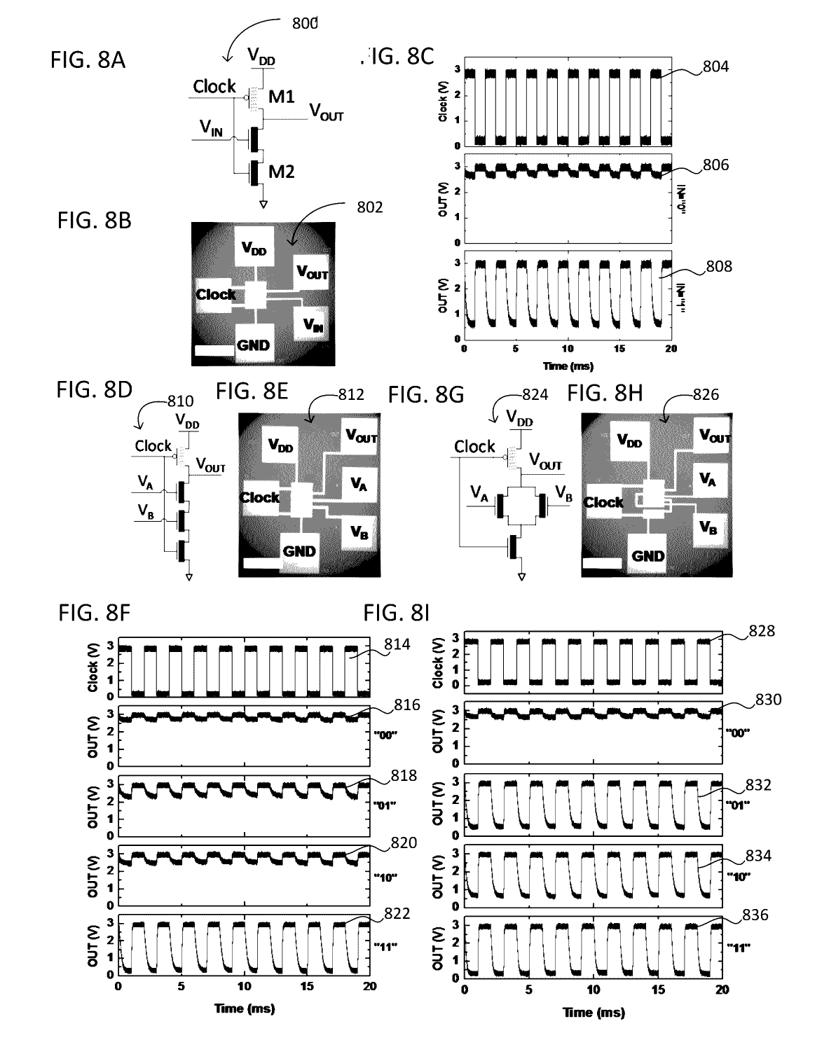

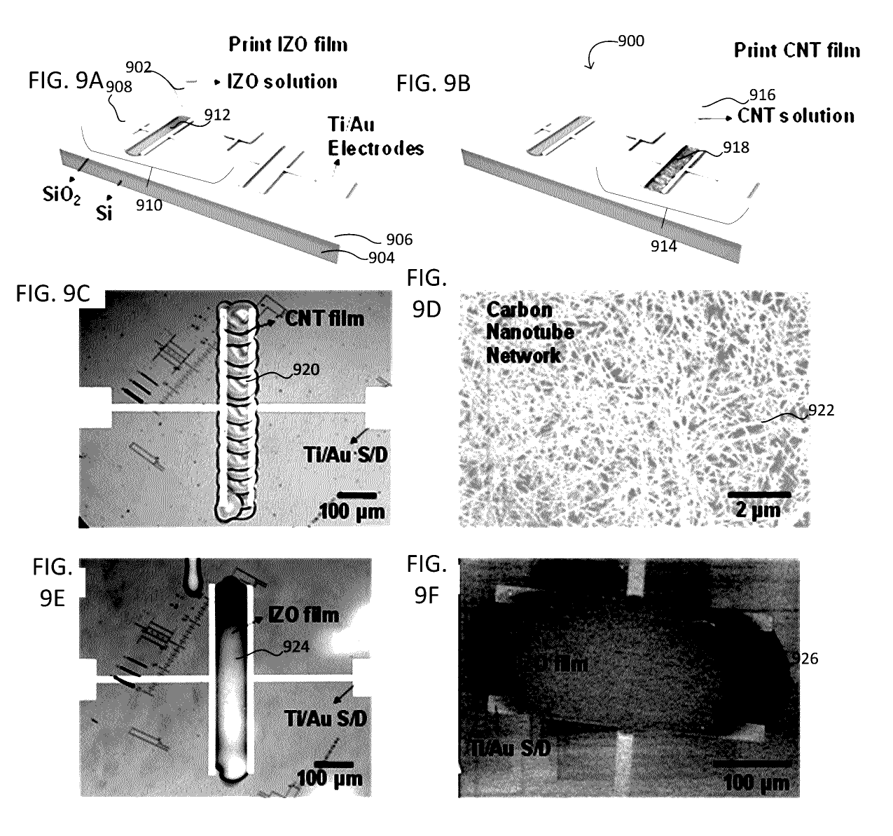

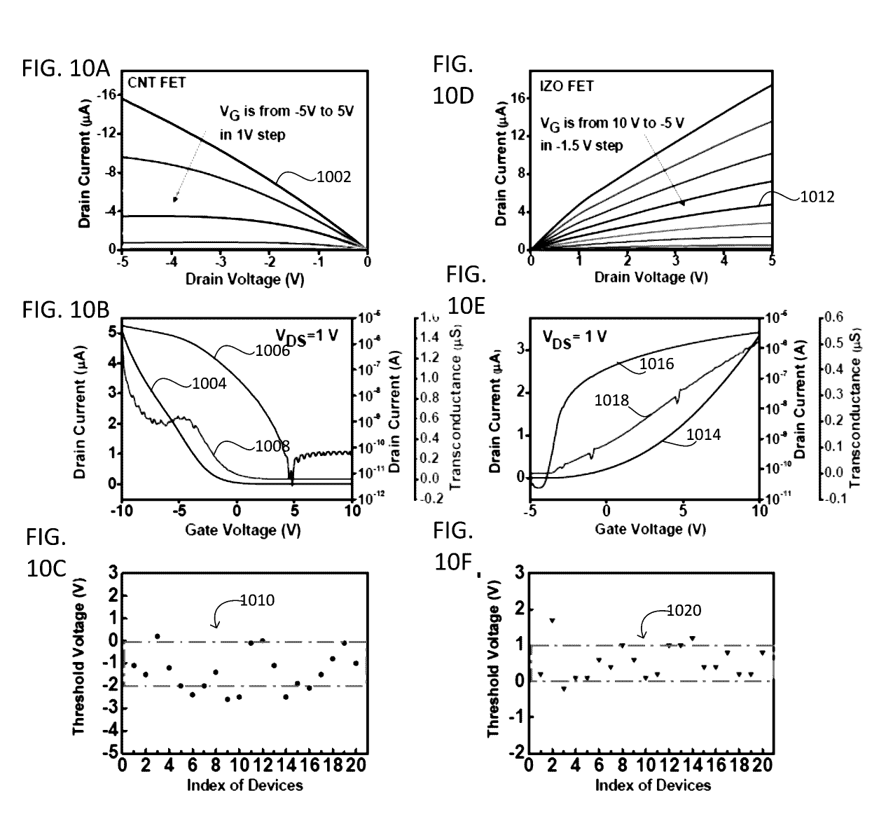

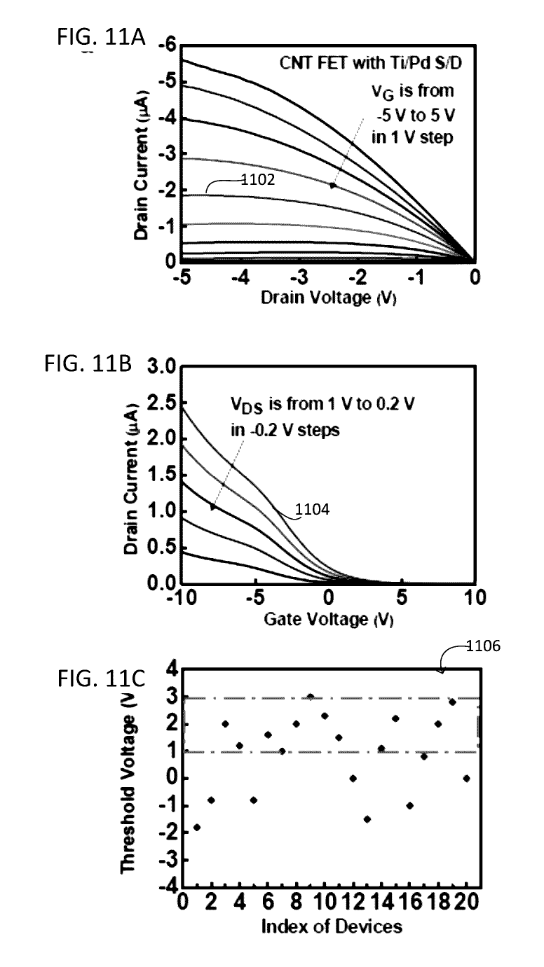

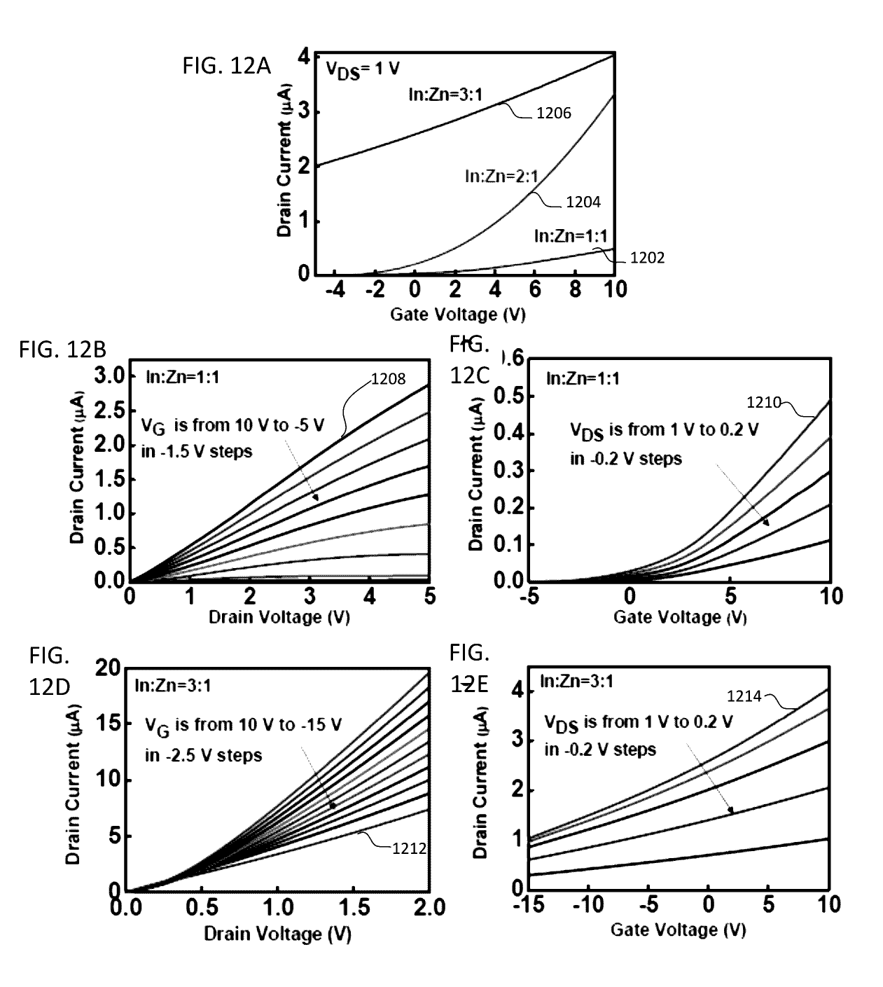

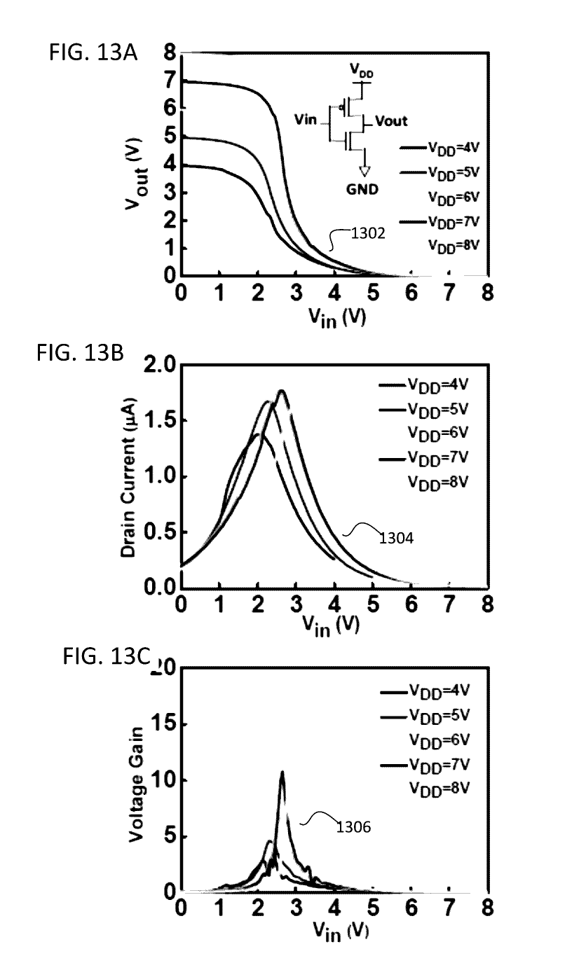

FIGS. 6B, 6D, 6F, and 6H show the oscillation frequency of ring oscillators decreases with increase in number of stages due to the effect of stage delay. This effect is depicted in FIG. 61. The oscillation frequencies is 1.96 kHz, 1.13 kHz, 648 Hz and 460 Hz for the 51-stage, 101-stage, 251-stage and 501-stage ring oscillators, respectively.

The stage delay of the 51-stage ring oscillator can be calculated with 1/2nf, n being the number of stages in an oscillator, and f being the oscillation frequency. The stage delay is found to be 5 μs, which is consistent for all the oscillators disclosed herein. Unlike systems based on p-type only inverters which showed oscillation that reached neither V_{DD} nor ground, all of ring oscillators disclosed herein can exhibit rail-to-rail switching between V_{DD} and ground.

The largest integration of hybrid CNT/IGZO circuit with a 501-stage ring oscillator described herein includes 1004 transistors as shown in the optical image in FIG. 6G. This large scale integrated (LSI) circuit is consisted of 501 inverters and a buffer stage. The V_{DD} of the circuit is 6V, and as can be observed in FIG. 5H, the output 616 of the oscillator shows a rail-to-rail voltage swing between V_{DD} and ground. The oscillation frequency of the circuit can reach 460 Hz, which is a result of combination of the stage delay across the circuit.

All of the aforementioned measurements were taken in ambient environment, indicating the stability of the CNT and IGZO transistors. In some embodiments, IGZO transistors can show reduction in on-state current by ˜30% after being kept in air for a week. This behavior may be due to interaction between IGZO thin film and oxygen and/or moisture in air. The deterioration of the electrical performance of the IGZO TFTs can saturate thereafter, as on-state current of the same IGZO TFT measured one year after its first characterization maintained a level that is ˜50% less than its first characterized value, i.e. from ˜10 μA to ˜5 μA. On the other hand, CNT transistors exhibited little degradation. After being stored in vacuum for one month, the 51-stage ring oscillator still operated correctly (i.e., returning the correct logic output), albeit at a reduced output amplitude.

Further passivation of the samples using dielectric material coating (e.g., Al₂O₃ ) can alleviate or eliminate the effect of degradation of the IGZO TFTs. The CNT/IGZO hybrid circuit platform provides a high-yield foundation for the integration with such unprecedented level of integration.

FIG. 6J shows the progress of the level of integration of carbon nanotube based circuits since the year 2006. A general trend of increment in the level of integration can be observed on the graph, and the methods and devices described herein are the first demonstration of large scale integrated circuits based on hybrid integration of 502 CNT transistors and 502 IGZO transistors.

FIG. 7A shows a hybrid complementary CNT/IGZO 251-stage ring oscillator 700 fabricated on a flexible polyimide film, and its corresponding output characteristic. For a supplied voltage of 6V, an output signal 702 of the ring oscillator 700 oscillated between 0 and 4V, at an oscillation frequency of 338 Hz is obtained.

FIG. 7B shows a hybrid CNT/IGZO 501-stage ring oscillator 704 fabricated on a flexible polyimide film. For a supplied voltage of 6V, an output signal 706 of the ring oscillator 704 oscillated between 0 and 1.8V, at an oscillation frequency of 294 Hz is obtained.

In addition to the static logic gates and ring oscillators, dynamic hybrid CNT/IGZO logic circuits are also implemented. Dynamic logic gates can refer to the operation of all dynamic logic gates that depends on temporary (transient) storage of charge in parasitic node capacitances, instead of relying on steady-state circuit behavior. Dynamic logic gates can increase the overall switching speed of the circuits and reduce static power dissipation comparing to static logic circuits.

FIG. 8A shows a dynamic inverter 800. In a dynamic inverter, a clock signal is sent into the circuit. FIG. 8B is an optical image of the inverter 802. The scale bar shown in FIG. 8B is 200 μm. When the clock signal is low, M1 is turned on to precharge the output parasitic capacitance to the level of V_{DD}, and M2 is off during this cycle of operation, and hence the input does not affect the output when the clock signal is low. When the clock signal is changed to high, M1 is turned off and M2 is turned on, at which the output is determined by the input signal, and this is the evaluating stage. The methods and devices described herein are the first demonstration of using CNT in a dynamic gate integrated circuit. A signal 804 shown in FIG. 8C is the clock signal that is set at 500 Hz. The V_{DD} of the inverter was held at 3V. When an input signal V_{IN} of “0” is applied to the dynamic inverter 802, an output signal 806 that varies as a function of time is obtained. Similarly, when an input signal V_{IN} of “1” is applied to the dynamic inverter 802, an output signal 808 is obtained.

For both signals 806 and 808, when clock is low, the output is “1” (near V_{DD}) regardless of the input. When the clock is high, the output is an inverted signal of the input, as expected. Equivalently, the output 806 of the inverter was observed to be near V_{DD} when the input was “0”, and the output 808 shows an inverted signal of the clock signal 804 when the input is set at “1”.

FIG. 8D shows a schematic diagram of a dynamic two-input NAND gate 810. FIG. 8E shows an optical image of a fabricated NAND gate 812. FIG. 8F shows a clock signal 814 at 500 Hz. When V_{DD} of 3V is provided, and when the inputs to both V_{A} and V_{B} are “0”, an output signal 816 is obtained. When V_{A} is “0” and V_{B} is “1”, an output 818 is obtained. When V_{A} is “1” and V_{B} is “0”, an output 820 is obtained. Output signals 816, 818, and 820 are all held near the V_{DD}. When both V_{A} and V_{B} are “1”, an output 822 returns an inverted signal of the clock signal 814. The output 816, 818, 820, and 822 are consistent with expected outputs of a NAND gate.

FIG. 8G shows a schematic diagram of a dynamic NOR gate 824. FIG. 8H shows an optical image of fabricated NOR gate 826. The scale bar shown in FIG. 8H is 200 μm. FIG. 8I shows a clock signal 828 at 500 Hz. When V_{DD} of 3V is provided, and when both V_{A} and V_{B} are “0”, an output signal 830 that is close to V_{DD} is obtained. When V_{A} is “0” and V_{B} is “1”, an output 832 is obtained. When V_{A} is “1” and V_{B} is “0”, an output 834 is obtained. When both V_{A} and V_{B} are “1”, an output 836 is obtained. Output signals 832, 834, and 836 all return an inverted signal of the clock signal 828. The output signals 830, 832, 834, and 836 are consistent with expected outputs of a NOR gate. The methods and devices described herein are first demonstrations of CNT based dynamic inverter NAND, and NOR gates. The hybrid circuit scheme enables the integration of more complicated circuits with the dynamic circuit building blocks.

Characterization of individual CNT and IGZO TFT, as well as static hybrid CNT/IGZO inverter, NAND and NOR logic gates can be conducted using an Agilent 4156B Precision Semiconductor Parameter Analyzer from Agilent of Santa Clara, Calif., under ambient environment. The ring oscillators can be characterized by supplying V_{DD} and ground to the circuits through a DC power source (HP 6632A System DC Power Supply from HP of Palo Alto, Calif.), and the output signals can be measured with an oscilloscope (Agilent Infinium MSO8104A). Measurements were performed on the dynamic inverter, NAND and NOR logic circuits with combined usage of the Semiconductor Parameter Analyzer and the oscilloscope. Input signals were supplied to the circuits with the Analyzer and the output signals were recorded with the oscilloscope. The flexible circuits were characterized with the same instruments as their rigid circuits counterparts.

Carbon nanotube and IGZO hybrid complementary TFTs can be used as building blocks to realize large scale integrated digital circuits with more than one thousand transistors. Operating the circuits in complementary mode can minimize the static state power dissipation in the circuits. The p-type CNT TFT transistors are fabricated using semiconducting enriched CNT solution. The performance of the transistors can be further improved by utilizing CNT solution with higher semiconducting purity.

The circuits can also operate on flexible polyimide substrates. In fact, high-yield of the devices on the substrate is obtained for some embodiments. Hybrid CNT/IGZO circuit scheme is thus suitable for flexible electronics. Even though IGZO thin films described above are fabricated with the sputtering technique, the material can also be printed during the fabrication procedure. CNT thin film has also been demonstrated to exhibit desirable printability and performance for printed electronics. The hybrid CNT/IGZO complementary circuit configuration can be used for large-scale and low cost printed electronics applications. The hybrid integration of p-type nanomaterial (e.g., CNT) thin-film transistors and n-type oxide semiconductor (e.g., IGZO) thin-film transistors can have great impact on various macroelectronic applications.

FIG. 9A shows a schematic diagram of a fabrication process of the inkjet printed integrated inverter 900 (shown in FIG. 9B). A back-gated indium zinc oxide (IZO) TFT 910 serves as the n-type metal-oxide-semiconductor (NMOS) transistor of the inverter. Briefly, an IZO precursor solution 902 is printed on a substrate 904. The substrate 904 can be Si, having a layer 906 of SiO₂. In some embodiments, the layer 906 can be 50 nm of SiO₂ that is thermally grown. The SiO₂ can act as the dielectric layer. Source and drain electrodes 908 are patterned onto the SiO₂ covered Si substrate 904 by photolithography. The electrodes 908 can be 1 nm/50 nm Ti/Au. The IZO precursor solution 902 is well-sonicated before being printed onto a channel region 912 as the active material of the NMOS transistor 910 via GIX Microplotter Desktop from Sonoplot Inc., of Middleton, Wisconsin. The sample is then air annealed at 500° C. for 1 hour to convert the printed precursor film to indium zinc oxides, which work as the active material in the NMOS transistor 910.

The solution 902 can be prepared by first dissolving indium (III) nitrate hydrate (In(NO₃)₃.xH₂O) and zinc acetate dihydrate (Zn(CH₃COO)₂2H₂O) into 2-methoxyethanol as precursors of indium oxide and zinc oxide with a concentration of 0.6 M and 0.3 M, respectively. The solutions can be stirred. For example, the solutions can be stirred at a speed of 3500 rpm at 50° C. for 1 h. Thereafter, the precursor solutions can be mixed in different ratios to get In:Zn of 1:1, 2:1 and 3:1. During the mixing process, ethanolamine can be added into the mixture as the stabilizer to improve the uniformity and viscosity of the solution 902 for inkjet printing. The volume concentration of the stabilizer added was found to be optimized at 32%. After the addition of ethanolamine, the solution can be stirred at 50° C. at 3500 rpm for 1 hour and then aged overnight.

FIG. 9B shows the printing process of a SWCNT TFT 914. A 98% semiconducting enriched SWCNT solution 916 is printed as the active material for the p-type metal-oxide-semiconductor (PMOS). The SWCNT solution 916 can be formulated using IsoNanotubes S DGU, obtained from Nanolntegris, Inc. of Menlo Park, Calif. For example, 1.0 mg of the material can be used in 100 of ml aqueous solution. The SWCNT solution 916 is printed as the active material for the PMOS transistor 914 of the inverter 900. Before printing of the SWCNT, the Si/SiO₂ substrate can be functionalized with aminopropyltriethoxysilane (APTES) to improve the adhesion between SWCNT and Si/SiO₂ substrates. For example, the Si/SiO₂ substrate can be immersed into diluted APTES solution (APTES:isopropanol alcohol (IPA)=1:10) for 10 minutes, which can form an amine-terminated monolayer on top of the substrate that can improve the adhesion between the carbon nanotubes and the oxide layer 906 on Si substrate 904. Then, the substrate was rinsed with IPA. After that, DGU separated 98% semiconducting enriched SWCNT solution (from Nanolntegris Inc. of Menlo Park, Calif.) can be printed in the channel region 918 as the active material of a PMOS transistor 914 via the inkjet printer. After printing of SWCNT, a 20-min baking at 80° C. can be done in air to evaporate the solvent. The sample can then be aged in air overnight before being rinsed with deionized (DI) water to remove sodium dodecyl sulfate residue from the CNT solution.

FIG. 9C shows a pre-annealing CNT film 920 that is preliminarily inspected with an optical microscope to assure its quality. The pre-annealing CNT film 920 of the CNT TFT has decent uniformity and carries no cracks. Then, Field Emission Scanning Electron Microscope (FESEM) was utilized to examine the uniformity and density of carbon nanotube networks in the channel region of the CNT TFT. FIG. 9D shows the FESEM image of carbon nanotube network in the channel region, where the CNT 922 density is approximately 26-35 tubes/μm², which is a fine density for thin film transistor applications.

FIG. 9E is an optical image of the printed IZO TFT 910 after the annealing process. An IZO layer 924 is of good shape and uniformity. Optimizing the amount of ethanolamine added in the precursor ink can lead to a well-controlled printing process to achieve the desired viscosity for inkjet printing. FIG. 9F is an FESEM image of a printed back-gated IZO TFT, showing the amorphous structure of the IZO thin film 926 after one hour of air annealing at 500° C.

Electrical characterizations were carried out for the inkjet printed back-gated CNT TFT. Most of the printed CNT devices exhibited on-state current (Iₒₙ) in the range between 0.8 and 9.5 μA with a gate bias of −10 V and a drain voltage of 1 V. The on/off current ratios of the devices are 10⁴˜10⁶ with mobility of 1-5 cm²/V·s and the threshold voltages (Vₜₕ) are between −1.0 and −3.0 V. The electrical characteristics of one representative CNT device with channel length (L) of 100 μm and channel width (W) of 500 μm is presented in FIGS. 10A and 10B. An output (I_{D}-V_{D}) characteristics curve 1002 of the representative CNT device exhibit saturation behavior when the drain voltage becomes more negative.

FIG. 10B shows the transfer (I_{D}-V_{G}) characteristics curve 1004 of the same device. The curve 1004 represents the transfer characteristics in linear scale. Iₒₙ is 5.2 μA when gate voltage is −10 V and drain voltage is 1 V. In addition, the threshold voltage to be around −1.4 V. The transfer characteristics in logarithmic scale shown by curve 1006 indicate that the on/off current ratio is 10⁶. The transconductance-gate voltage (gₘ-V_{G}) characteristics curve 1008 shows the peak transconductance and the mobility of this CNT device to be 1.5 μS and 4.38 cm²/V·s based on parallel plate model.

A statistical analysis was carried out for the threshold voltages of 20 printed CNT devices. FIG. 10C shows a scatter plot 1010 of the threshold voltage. Most devices show threshold voltage of −1.0V˜3.0V, which indicates that most CNT devices were operating in enhancement mode.

FIG. 10D shows the output electrical performances (I_{D}-V_{D}) of the printed IZO TFTs in saturation regime. Most IZO TFTs showed Iₒₙ of 0.6˜5.2 μA under 10 V of gate voltage and 1 V of drain voltage, on/off current ratio of 10⁴˜10⁶, mobility of 1.0˜14.1 cm²/V·s and Vₜₕ of 0 V˜1 V. FIG. 10D shows the I_{D}-V_{D} family curves of one representative IZO device with L=100 μm and W=100 μm. Saturation behavior is observed as V_{D} becomes more positive, for example, as shown by curve 1012.

FIG. 10E shows the transfer characteristics (I_{D}-V_{G}) of the same IZO device in both linear (by curve 1014) and logarithmic (by curve 1016) scales, and the plot of gm versus V_{G} (by curve 1018 curve) measured at V_{D}=1V. The IZO device has Iₒₙ of 3.3 μA, Vₜₕ of 0.2 V, on/off current ratio of 10⁵, peak g_{m of} 0.5 μS and mobility of 7.36 cm²/V˜s.

FIG. 10F shows a scatter plot 1020 used for statistical analysis of the threshold voltage of 20 inkjet printed back-gated IZO TFTs. Most IZO devices had Vₜₕ between 0 V to 1.0 V and were in enhancement mode.

Source and drain electrodes fabricated from Ti/Pd were used to study the effects of metal electrodes on device performance. In the described embodiments, 1 nm of Ti and 50 nm of Pd were used to form the electrodes of printed CNT TFTs. The majority of CNT devices with Ti/Pd electrodes show Iₒₙ of 0.5˜9 μA, on/off current ratio of 10³˜10⁶, mobility of 0.50˜2.39 cm²/V·s and Vₜₕ of 1.0˜3.0 V. The electrical characteristics of one of these devices (L=100 μm, W=500 μm) are shown in FIGS. 11A and 11B.

FIG. 11A shows the output (I_{D}-V_{D}) characteristics of a representative CNT TFT (L=100 μm, W=500 μm) in saturation regime. The I_{D}-V_{D} curves, including curve 1102, in FIG. 11A demonstrate a saturation behavior as V_{D} becomes more negative. FIG. 11B shows I_{D}-V_{G} characteristics curves including curve 1104 where the drain voltage is at 1V. The curves are measured at different values of V_{DS} in steps of −0.2V from 1V to 0.2 V. In FIG. 11B, Iₒₙ is apparently 2.45 μA when gate voltage is −10 V and drain voltage is 1 V, Vₜₕ is 1.2 V, and the on/off current ratio of the same device is 10⁵. The maximum gm of this device is 0.32 μS; subsequently, the mobility is calculated to be 1.38 cm²/V·s. FIG. 11C shows a scatter plot 1106 used in a statistical analysis of threshold voltage distribution among 20 printed CNT TFTs with Ti/Pd as source and drain electrodes. Most of the devices have Vₜₕ of 1˜3 V, indicating that the majority is operating in depletion mode, as opposed to those with Ti/Au metal contacts (shown in FIG. 10C). Ti/Pd electrodes can thus cause the right shift of the threshold voltage of CNT TFTs relatively to that of Ti/Au electrodes.

The conduction of holes between the electrode and the CNT channel can be influenced by the alignment between the Fermi energy level of the metal and the valence band of the CNT. The work function of Pd is around 5.1 eV which is similar to the work function of CNT, allowing the energy barrier between the metal electrode and the CNT to be lowered. This results in lowering the energy barrier for carrier conduction, and hence shifts the threshold voltage to the right. Thus, TFTs with Ti/Pd electrodes can exhibit a more positive threshold voltage.

Effects of molar ratio of In to Zn in the IZO precursor solution on the electrical performances of TFTs are shown in FIGS. 12A-12E. FIG. 12A shows the transfer characteristics (I_{D}-V_{G}) of the printed IZO devices with In:Zn of 1:1, 2:1 and 3:1 represented by curves 1202, 1204, and 1206, respectively, as measured at V_{D}=1 V. Higher In-to-Zn ratio can result in higher mobility and on current, lower on/off current ratio and apparent Vₜₕ shifting to the left. As indium component increased two and threefold, carrier mobility rose dramatically from 1.11 cm²/V·s to 7.36 cm²/V·s and subsequently as high as 31.74 cm²/V·s while Iₒₙ (V_{DS}=1 V, V_{G}=10 V) increased from 0.49 μA to 3.3 μA and 4.1 μA correspondingly.

Devices with In:Zn=1:1 and 2:1 had about the same on/off current ratios on average since I_{off} also increased with Iₒₙ. However, when the In:Zn was increased to 3:1, I_{off} increased much faster than Iₒₙ resulting in a lower on/off current ratio. The on/off current ratios of the 1:1 and 2:1 devices shown in FIG. 12A are about the same (i.e., ˜10⁵) whereas that of the 3:1 device can abruptly drop to as low as 4. Moreover, the first two show positive Vₜₕ while the latter shows negative Vₜₕ, indicating its operation in depletion mode.

IZO TFTs with In:Zn=1:1 may therefore have a sub-optimal Iₒₙ while those with 3:1 can have sub-optimal on/off current ratios and operate in depletion mode. A In:Zn ratio of 2:1 may thus offer the best overall performance with the combination of desirable on current, mobility, on/off current ratio and threshold voltage. The detailed information of IZO TFT with In:Zn=2:1 shown in FIGS. 10D and 10E have been discussed above.

FIGS. 12B and 12C show I_{D}-V_{D} and I_{D}-V_{G} curves, respectively, for a representative IZO device (L=100 μm, W=100 μm) with In:Zn=1:1 in saturation regime. A curve 1208 shows the variation of drain current as a function of drain voltage between 0V to 5V when the gate voltage is held at 10V. A curve 1210 shows the variation of drain current as a function of gate voltage between −5V to 10V, when the drain voltage is fixed at 1V. The device shows Iₒₙ of 0.49 μA, Vₜₕ of 1 V, on/off current ratio of 10⁵ and carrier mobility of 1.11 cm²/V·s.

FIGS. 12D and 12E show that a IZO device with In:Zn=3:1 does not get fully depleted even at V_{G}=−15 V. The curve 1212 shows the variation of drain current as a function of drain voltage when the gate voltage is −15V. As is evident from their high drain currents at relatively high negative V_{G}, most of IZO devices with In:Zn=3:1 work in depletion mode. Curve 1214 shows the variation of drain current as a function of gate voltage when the drain voltage is held at 1V. Indium oxide has the highest mobility among the oxides of In, Ga and Zn due to its large amount of oxygen vacancies, which could contribute to the carrier concentration. High carrier concentration can make it challenging to bring down the I_{off}, which results in a lower on/off current ratio.

The capability of printing both CNT TFTs and IZO TFTs with desirable mobility, controlled threshold voltage and good on/off current ratio allows the construction of high quality complementary digital circuits through the inkjet printing approach. A printed complementary inverter was achieved based on the thin films of CNT and IZO.

Voltage transfer (V_{IN}-V_{OUT}) curves provide information about CMOS circuits' static performance. In FIG. 13A, voltage transfer characteristics (V_{OUT}-V_{IN}) of one typical complementary inverter are illustrated at various supply voltages ranging from 4 V to 8 V in 1 V step. Curve 1302 shows the variation of the output voltage as a function of the input voltage when the supplied voltage V_{DD} is 8V. Ideally, the output voltage switches from “1” state (8 V) to “0” state (0 V) when the input signal is swept from the “0” state (0 V) towards the “1” state (8 V) and vice versa. The inverter shown in FIG. 13A has output levels that are very close to corresponding supply voltage (V_{DD}) and low output levels that are approximately 0. Considering V_{DD}=8 V (curve 1302) as an example, the output swing reaches 7.97 V, which is 99.6% of V_{DD}.

Ideally, one transistor of the CMOS inverter is always off. However, during the switching state there can be a rapid moment where both pull-up and pull-down circuits are on. Pull-up circuit is the circuit connected between the output signal Vₒᵤₜ conductor and the supplied voltage V_{DD}. Pull-down circuit is the circuit connected between ground the output signal Vₒᵤₜ conductor. As a result, there is a direct current flow from V_{DD} to ground causing power dissipation that is called dynamic short-circuit power. This power dissipated is directly proportional to I_{D}_{ₘₐₓ}, which is the peak value of the drain current of I_{D}-V_{IN} curve.

FIG. 13B shows I_{D}-V_{IN} characteristic curves of the inverter. When the inverter is operating in close proximity to either “0” or “1” state, its I_{D} is near zero, indicating little power loss during this period. When switching, ID dramatically rises and reaches maximum before attenuating to nearly zero. Curve 1304 shows the variation of the drain current I_{D} when V_{DD} is fixed at 8V, for input voltage V_{IN} ranging from 0V to 8V.

FIG. 13C shows the voltage gain of the same inverter measured at different V_{DD} ranging from 4 V to 8 V in 1 V. At V_{DD}=8 V, as shown by curve 1306, the inverter manifested a sharp turn at the switching threshold of about 3V, where the gain is read out to be 16.9.

Inkjet printed complementary circuits based on CNT and IZO thin film transistors described herein show excellent electrical performance. The CNT thin film transistors exhibited highest Iₒₙ of 9.5 μA, on/off ratio of 10⁴˜10⁶ and maximum mobility of 5 cm²/V·s while our IZO thin film transistors reached Iₒₙ of 5.2 μA, on/off ratio of 10⁴˜10⁶ and mobility as high as 14.1 cm²/V·s.

Ti/Pd electrodes shift the threshold voltages of CNT TFTs to the right relative to that of Ti/Au electrodes. IZO TFTs having In-to-Zn ratios of 2:1 can provide better performance than those with ratios of 1:1 and 3:1. In terms of the size of the on current, on/off current ratio, mobility and threshold voltage.

A CMOS inverter was fabricated by sequentially printing IZO and CNT solutions as the active materials onto the same Si/SiO₂ substrate with pre-patterned Ti/Au electrodes. The inverter can provide a maximum output swing of 99.6% V_{DD} and a voltage gain of 16.9 (with V_{DD}=8 V). These results confirm that CNT and IZO are outstanding materials for p-type and n-type transistors while inkjet printing has great potential in allowing the two types of transistors to be produced on the same substrate for a CMOS circuit through a simple, reproducible, and low cost approach. Additional printed CMOS circuits with more sophisticated logic and even superior performance can be fabricated based on the methods disclosed herein.

In general, instead of an IGZO thin film, the methods and devices disclosed herein can include metal oxide thin films such as zinc-tin-oxide (ZTO), indium-zinc-oxide (IZO), indium-zinc-tin-oxide (IZTO), aluminum-indium-oxide (AIO), zinc oxide (ZnO) and indium oxide (In₂O₃) prepared with both solution-based processes and standard evaporation or sputtering processes.

In addition or alternative to using carbon nanotube in the TFT, other nanomaterials, such as graphene, MoS₂, WS₂, MoSe₂, NbSe₂, TaSe₂, NiTe₂, MoTe₂, h-BN, Bi₂Te₃, TiS₂, TaS₂VSe₂ and ZrS₂ can also be used.

Further modifications and alternative embodiments of various aspects will be apparent to those skilled in the art in view of this description. Accordingly, this description is to be construed as illustrative only. It is to be understood that the forms shown and described herein are to be taken as examples of embodiments. Elements and materials may be substituted for those illustrated and described herein, parts and processes may be reversed, and certain features may be utilized independently, all as would be apparent to one skilled in the art after having the benefit of this description. Changes may be made in the elements described herein without departing from the spirit and scope as described in the following claims.

What is claimed is:

1. A method of fabricating a logic element, the method comprising:
forming a p-type nanomaterial thin film transistor on a substrate;
forming a n-type metal oxide thin film transistor on the substrate; and
connecting the p-type nanomaterial thin film transistor to the n-type metal oxide thin film transistor to form the logic element, wherein the logic element is a hybrid complementary logic element.

2. The method of claim 1, wherein forming the p-type nanomaterial thin film transistor comprises:
dispensing a solution of the nanomaterial on a dielectric layer formed on the substrate; and
forming a nanomaterial channel comprising the nanomaterial between electrodes formed on the dielectric layer.

3. The method of claim 1, wherein forming the n-type metal oxide thin film transistor comprises:
depositing, by sputtering, a metal oxide thin film on a dielectric layer formed on the substrate;
patterning electrodes on the metal oxide thin film to form the n-type metal oxide thin film transistor.

4. The method of claim 1, wherein forming the n-type metal oxide thin film transistor comprises printing a precursor solution between electrodes formed on a dielectric layer that is formed on the substrate, and annealing the deposited precursor solution to form the n-type metal oxide thin film transistor.

5. The method of claim 1, wherein the substrate comprises flexible polyimide.

6. The method of claim 1, wherein the nanomaterial thin film comprises an element selected from the group consisting of carbon nanotubes, graphene, MoS₂, WS₂, MoSe₂, NbSe₂, TaSe₂, NiTe₂, MoTe₂, h-BN, Bi₂Te₃, TiS₂, TaS₂, VSe₂ and ZrS₂.

7. The method of claim 1, wherein the metal-oxide thin film comprises an element selected from the group consisting of indium gallium zinc oxide (IGZO), zinc tin oxide (ZTO), indium zinc oxide (IZO), indium zinc tin oxide (IZTO), aluminum oxide (AIO), zinc oxide (ZnO) and indium oxide (In₂O₃).

8. The method of claim 1, wherein the metal-oxide thin film comprises IGZO and the nanomaterial thin film comprises carbon nanotubes.

9. A method of forming macroelectronics, the method comprising electrically connecting a plurality of logic elements fabricated using the method of claim 1.

10. The method of claim 9, wherein the macroelectronics comprise flat-panel displays.

11. A logic element, the logic element comprising:
a substrate;
a p-type nanomaterial thin film transistor on the substrate; and
a n-type metal oxide thin film transistor in electrical connection with the p-type nanomaterial thin film transistor on the substrate.

12. The logic element of claim 11, wherein the nanomaterial comprises an element selected from the group consisting of carbon nanotube, graphene, MoS₂, WS₂, MoSe₂, NbSe₂, TaSe₂, NiTe₂, MoTe₂, h-BN, Bi₂Te₃, TiS₂, TaS₂, VSe₂ and ZrS₂.

13. The logic element of claim 11, wherein the metal-oxide thin film comprises an element selected from the group consisting of indium gallium zinc oxide (IGZO), zinc tin oxide (ZTO), indium zinc oxide (IZO), indium zinc tin oxide (IZTO), aluminum oxide (AIO), zinc oxide (ZnO) and indium oxide (In₃).

14. The logic element of claim 11, wherein the p-type nanomaterial thin film transistor comprises a carbon nanotube thin film transistor, and the n-type metal oxide thin film transistor comprises an indium gallium zinc oxide (IGZO) thin film transistor.

15. The logic element of claim 14, wherein the logic element comprises a dynamic inverter and the carbon nanotubes thin film transistor is configured to be gated by a clock signal.

16. A ring oscillator comprising a plurality of the logic elements of claim 14, wherein the ring oscillator is configured to rail-to-rail switch between a supplied voltage and ground.

17. The logic element of claim 14, wherein the logic element comprises a NAND gate.

18. Large-scale macroelectronics comprising at least 200 of the logic elements of claim 11.

19. The logic element of claim 11, wherein the p-type nanomaterial thin film transistor comprises a carbon nanotube thin film transistor, the n-type metal oxide thin film transistor comprises an indium zinc oxide (IZO) thin film transistor, and the logic element comprises an inverter having an output swing of more than 98% and a voltage gain of more than 15.

20. The logic element of claim 19, wherein an In to Zn ratio in the IZO thin film is 2:1.

21. The logic element of claim 19, wherein the IZO thin film transistor comprises Ti/Au electrodes.

22. The logic element of claim 11, wherein the substrate is a flexible substrate.
